(19) United States
(12) Patent Application Publication
(10) Pub. No.: US 2006/0139995 A1
(43) Pub. Date: Jun. 29, 2006

(54) One time programmable memory

(76) Inventors: Ali Keshavarzi, Portland, OR (US); Fabrice Paillet, Hillsboro, OR (US); Muhammad M. Khellah, Tigard, OR (US); Dinesh Somasekhar, Portland, OR (US); Yibin Ye, Portland, OR (US); Stephen H. Tang, Pleasanton, CA (US); Mohsen Alavi, Portland, OR (US); Vivek K. De, Beaverton, OR (US)

Correspondence Address: LeMoine Patent Services, PLLC;PortfolioIP, P.O. Box 52050, Minneapolis, MN, 55402, US

(21) Appl. No.: 11/027,476

(22) Filed: Dec. 28, 2004

(51) Int. Cl. G11C 11/34

(52) U.S. Cl. 365/177

(57) ABSTRACT

A one time programmable memory includes isolated gate transistors that may be programmed by subjecting the isolated gate transistors to voltage conditions that degrade characteristics of the isolated gate transistors. The degraded characteristics may be sensed to read the memory.

### FIELD

The present invention relates generally to memory circuits, and more specifically to one time programmable memory circuits.

### BACKGROUND

One time programmable (OTP) memories may be manufactured using various technologies. For example, polysilicon fuses may be utilized as memory elements in OTP memories. Polysilicon fuses are typically thermally blown to store a memory state.

### BRIEF DESCRIPTION OF THE DRAWINGS

FIG. 1 shows a memory cell with supporting circuits;

FIG. 2 shows a one time programmable (OTP) memory device;

FIG. 3 shows a system diagram in accordance with various embodiments of the present invention; and

FIG. 4 shows a flowchart in accordance with various embodiments of the present invention.

### DESCRIPTION OF EMBODIMENTS

In the following detailed description, reference is made to the accompanying drawings that show, by way of illustration, various embodiments in which the invention may be practiced. These embodiments are described in sufficient detail to enable those skilled in the art to practice the invention. It is to be understood that the various embodiments of the invention, although different, are not necessarily mutually exclusive. For example, a particular feature, structure, or characteristic described herein in connection with one embodiment may be implemented within other embodiments without departing from the spirit and scope of the invention. In addition, it is to be understood that the location or arrangement of individual elements within each disclosed embodiment may be modified without departing from the spirit and scope of the invention. The following detailed description is, therefore, not to be taken in a limiting sense, and the scope of the present invention is defined only by the appended claims, appropriately interpreted, along with the full range of equivalents to which the claims are entitled. In the drawings, like numerals refer to the same or similar functionality throughout the several views.

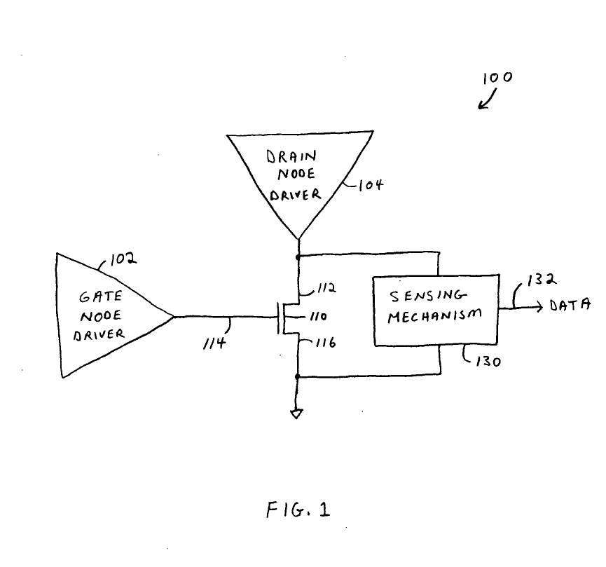

FIG. 1 shows a memory cell with supporting circuits. Circuit 100 includes transistor 110, gate node driver 102, drain node driver 104, and sensing mechanism 130. Transistor 102 is an isolated gate transistor having a gate node 114, a source node 116 and a drain node 112. Source node 116 is coupled to a reference node, gate node 114 is coupled to be driven by gate node driver 102, and drain node 112 is coupled to be driven by drain node driver 104. Sensing mechanism 130 is coupled between drain node 112 and source node 116 of transistor 110 to sense one or more characteristics of transistor 110.

As further described below, in various embodiments of the present invention, transistor 110 may be subjected to overvoltage conditions by one or more of drain node driver 104 and gate node driver 102. These overvoltage conditions change one or more characteristics of transistor 110. In some embodiments, the change in transistor characteristics is a permanent change. In these embodiments, transistor 110 may be “programmed” by changing its characteristics, or may be left “unprogrammed” by not changing its characteristics. Sensing mechanism 130 senses the change in characteristics and provides an indication of the programmed state on data node 132.

Transistor 110 is shown as an isolated gate transistor, and specifically as an n-channel metal oxide semiconductor field effect transistor (NMOSFET). Other types of devices subject to characteristic changes due to overvoltage conditions may be utilized for transistors shown in the various figures without departing from the scope of the present invention. For example, transistor 110 may be a p-channel metal oxide semiconductor field effect transistor (PMOSFET) or any other device capable of performing as described herein.

An isolated gate transistor conducts a certain amount of current based on its threshold voltage value and the voltage across its various nodes, or “terminals.” When a high voltage is applied between the drain and source terminals and between the gate and source terminals, the transistor characteristics may degrade. For example, when a gate and drain of a transistor see a high voltage relative to its source terminal, the transistor is biased in a high impact ionization region and may degrade due to hot carriers (“hot carrier degradation”). Operation in the high impact ionization region produces damage to material that insulates the gate terminal (“gate insulator material”), and charge trapping that changes characteristics of the transistor. When a transistor is damaged by charge trapped inside the gate insulator, the transistor threshold voltage may shift, and the transistor may conduct a different amount of current.

Sensing mechanism 130 may be any suitable circuit to sense the degradation of transistor 110 due to the overvoltage condition. For example, sensing mechanism 130 may compare a current conducted through transistor 110 to a reference current. Also for example, sensing mechanism 130 may detect a voltage change across the terminals of transistor 110. The various embodiments of the present invention are not limited by the operation of sensing mechanism 130. Any suitable sensing mechanism may be employed without departing from the scope of the present invention.

In operation, transistor 110 may be “programmed” by applying a high voltage to drain node 112 and gate node 114 relative to source node 116. Further, transistor 110 may be held in a “standby” state by applying a low voltage to gate node 114, and transistor 110 may be “read” by applying nominal voltages to drain node 112 and gate node 114, and sensing the drain-to-source current of transistor 110. Table 1, below, shows possible voltage values for programming and reading the memory cell represented by transistor 110.

TABLE 1

| | Drain Node 112 | Gate Node 114 |
|---|---|---|
| Program | Very High | Very High |
| Read | High | Medium |
| Standby | XX | Low |

The relative voltage values listed in Table 1 include “XX,” “Low,” “Medium,” “High,” and “Very High.” XX is meant to signify that any reasonable voltage value with suffice. For example, when in standby, transistor 110 is off, and the drain node may be driven with any suitable voltage value that will keep transistor 110 turned off. A Low voltage in the context of Table 1 is a voltage below the threshold voltage of transistor 110. For example, in some embodiments, a Low voltage may be the same voltage that is present on source node 116.

A Medium voltage in the context of Table 1 is a voltage that approximates the threshold voltage of transistor 110. When a Medium voltage is applied to the gate node of transistor 110, the transistor will turn on, and the amount of drain-to-source current will depend in part on whether transistor 110 has been programmed. Sensing mechanism 130 may then sense whether transistor 110 has been programmed or not.

A High voltage in the context of Table 1 is a voltage that is higher than the Medium voltage, but below a voltage level sufficient to change the characteristics of transistor 110. For example, in some embodiments, a High voltage may be equal to an upper power supply voltage, sometimes referred to as “Vcc.” A Very High voltage in the context of Table 1 is a voltage high enough to change characteristics of transistor 110 when applied. In some embodiments, a Very High voltage may be a voltage that is above an upper power supply voltage. For example, in some embodiments, a Very High voltage may be approximately 1.4 times an upper power supply voltage, or higher.

As shown in Table 1, transistor 110 may be programmed by applying a Very high voltage to both the drain node and gate node of transistor 110. In other embodiments, transistor 110 may be programmed by applying a Very high voltage to the drain node, and a High voltage to the gate node. In various other embodiments of the present invention, other voltage combinations may be used to program transistor 110 by changing its characteristics.

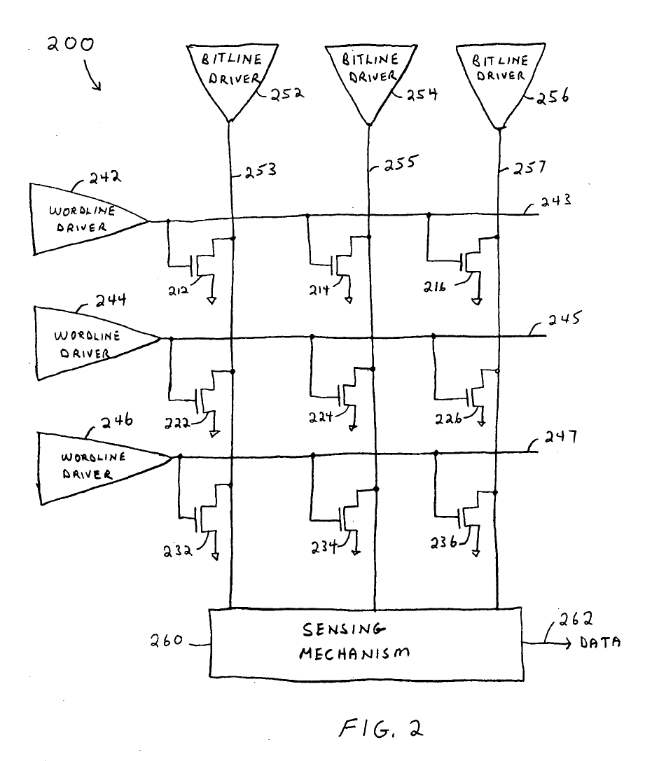

FIG. 2 shows a one time programmable (OTP) memory device. Memory device 200 includes an array of memory cells that include transistors coupled to wordlines and bitlines. The wordlines are driven by wordline drivers, and the bitlines are driven by bitline drivers. The bitlines are also coupled to a sensing mechanism to sense the contents of the memory cells.

The array of transistors includes transistors 212, 214, 216, 222, 224, 226, 232, 234, and 236. The wordline drivers include wordline drivers 242, 244, and 246, and the bitline drivers include bitline drivers 252, 254, and 256. Wordline driver 242 drives wordline 243; wordline driver 244 drives wordline 245; and wordline driver 246 drives wordline 247. Bitline driver 252 drives bitline 253; bitline driver 254 drives bitline 255; and bitline 256 drives bitline 257.

Memory device 200 is a one-time-programmable memory having an addressable array of isolated gate transistors. Each transistor in the array may be individually selected and “programmed” by causing gate insulator degradation as described above with reference to FIG. 1. Each of the isolated gate transistors is coupled to one bitline and one wordline, and may be programmed when a Very High voltage is present on the bitline and wordline. For example, transistor 224 may be programmed when wordline driver 244 drives wordline 245 with a Very High voltage, and bitline driver 254 drives bitline 255 with a Very High voltage. Under these conditions, an impact ionization current is created, the gate insulator material of transistor 224 is degraded, and transistor 224 is programmed as a result.

In the example of the previous paragraph, wordline drivers 242 and 246 drive a voltage other than Very High on their respective word lines, and bitline drivers 252 and 256 drive a voltage other than Very High on their respective bit lines. For example, in some embodiments, when transistor 224 is programmed, bitline drivers 252 and 256 may drive a Low, Medium, or High voltage on their respective bitlines, and wordline drivers 242 and 246 may drive a Low voltage on their respective wordlines.

Memory device 200 may be read by selecting a row of memory cells. For example, the row of memory cells corresponding to wordline 245 may be selected by wordline driver 244 driving a Medium voltage on wordline 245. During this read cycle, wordline drivers 242 and 246 drive a Low voltage to turn off the transistors in other rows. Transistors that have been programmed through gate insulator degradation will have a higher threshold voltage than the unprogrammed transistors. For example, in the example above in which transistor 224 was programmed, transistor 224 would have a higher threshold voltage than transistors 222 and 226.

Sensing mechanism 260 includes circuitry to sense which of the bitlines are coupled to programmed cells and which bitlines are coupled to unprogrammed cells. For example, sensing mechanism 260 may include current sources, switches, current mirrors, comparators, or any other useful circuits. Sensing mechanism 260 may determine whether each cell holds a logical “1” or “0” based on whether the cell is programmed or not, and may output digital data at 262.

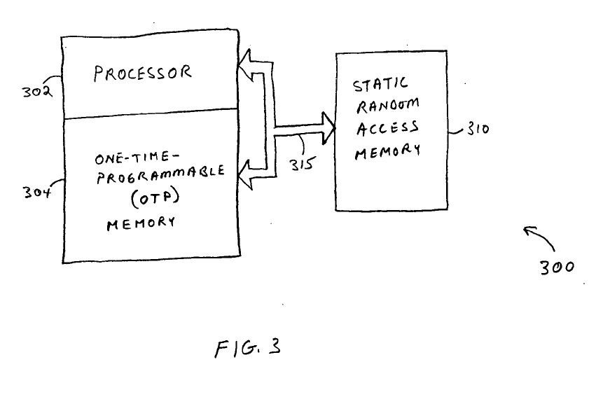

FIG. 3 shows a system diagram in accordance with various embodiments of the present invention. Electronic system 300 includes processor 302, OTP memory device 304 and static random access memory (SRAM) 310 interconnected by conductor 315. Processor 302 may be any type of processing apparatus capable of communicating with OTP memory device 304 and SRAM 310. For example, processor 302 may be a microprocessor, a digital signal processor, a microcontroller, an application specific integrated circuit (ASIC), a memory controller, or the like. OTP memory 304 may be any of the memory embodiments described with reference to the previous figures.

In some embodiments, processor 302 and OTP memory 304 are separate devices that are combined when electronic system 300 is assembled. For example, processor 302 and OTP memory 304 may be separately packaged integrated circuit dice coupled to the same circuit board. In other embodiments, processor 302 and OTP memory 304 are included in the same package, or on the same integrated circuit die. For example, in some embodiments, OTP memory 304 may be a microprogram control store included on the same integrated circuit die as processor 302. Also for example, in some embodiments, OTP memory 304 may be a small read only memory used to hold a serial number or other identifying indicia for processor 302.

The type of interconnection between processor 302, OTP memory 304, and SRAM 310 is not a limitation of the present invention. For example, conductor 315 may be a bus, a serial interface, a test interface, a parallel interface, or any other type of interface capable of transferring information between the various devices shown in FIG. 3.

Electronic system 300 may be an end user system. For example, electronic system 300 may be a consumer electronics device such as a cell phone, a notebook computer, a network interface card (NIC), or the like. Electronic system 300 may also be a system used to program OTP memory 304. For example, electronic system 300 may be part of a station in an assembly or test environment. OTP memory 304 may be programmed as part of a wafer level test, as part of an assembly process for a higher level subsystem, or by an end user.

Although OTP memory 304 is shown in electronic system 300 coupled to a SRAM, the use of OTP memory 304 is not so limited. For example, OTP memory 304 may be utilized in many different types of systems and applications that do not include SRAM. These systems may use dynamic random access memory (DRAM), Flash memory, or many other different types of memory.

Integrated circuits, memory devices, sensing mechanisms, and other embodiments of the present invention can be implemented in many ways. In some embodiments, they are implemented in integrated circuits. In some embodiments, design descriptions of the various embodiments of the present invention are included in libraries that enable designers to include them in custom or semi-custom designs. For example, any of the disclosed embodiments can be implemented in a synthesizable hardware design language, such as VHDL or Verilog, and distributed to designers for inclusion in standard cell designs, gate arrays, or the like. Likewise, any embodiment of the present invention can also be represented as a hard macro targeted to a specific manufacturing process. For example, the array of memory cells shown in FIG. 2 may be represented as polygons assigned to layers of an integrated circuit.

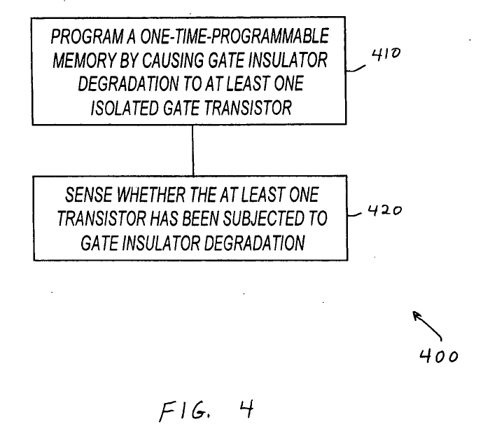

FIG. 4 shows a flowchart in accordance with various embodiments of the present invention. In some embodiments, method 400, or portions thereof, is performed by a one time programmable memory circuit, embodiments of which are shown in previous figures. In other embodiments, method 400 is performed by a control circuit, an integrated circuit, or an electronic system. Method 400 is not limited by the particular type of apparatus performing the method. The various actions in method 400 may be performed in the order presented, or may be performed in a different order. Further, in some embodiments, some actions listed in FIG. 4 are omitted from method 400.

Method 400 is shown beginning with block 410 in which a one-time-programmable memory is programmed by causing gate insulator degradation to at least one isolated gate transistor. For example, one or more transistors in an array may be programmed by applying voltages high enough to gate and drain nodes to cause impact ionization current and gate insulator degradation.

At 420, the at least one transistor is sensed to determine whether the at least one transistor has been subjected to gate insulator degradation. In some embodiments, this may correspond to sensing a change in an operating characteristic of the at least one transistor. For example, in some embodiments, a sensing mechanism may sense whether a threshold voltage of the at least one transistor has changed.

Although the present invention has been described in conjunction with certain embodiments, it is to be understood that modifications and variations may be resorted to without departing from the spirit and scope of the invention as those skilled in the art readily understand. Such modifications and variations are considered to be within the scope of the invention and the appended claims.

What is claimed is:

1. An apparatus comprising:
an addressable array of isolated gate transistors;
driver circuitry coupled to the addressable array of isolated gate transistors to cause gate insulator degradation; and
sensing circuitry to read the addressable array.

2. The apparatus of claim 1 wherein the sensing circuitry is coupled to sense whether isolated gate transistors have been subjected to gate insulator degradation.

3. The apparatus of claim 2 wherein the sensing circuitry is coupled to sense threshold voltage changes.

4. The apparatus of claim 1 further comprising bit lines coupled to drain nodes of the isolated gate transistors.

5. The apparatus of claim 4 further comprising wordlines coupled to gate nodes of the isolated gate transistors.

6. The apparatus of claim 5 wherein the driver circuitry comprises circuitry to drive a voltage higher than a nominal power supply voltage onto the wordlines.

7. The apparatus of claim 5 wherein the driver circuitry comprises circuitry to drive a voltage higher than a nominal power supply voltage onto the bitlines.

8. The apparatus of claim 1 wherein the addressable array of isolated gate transistors includes MOSFET transistors.

9. The apparatus of claim 1 wherein the addressable array of isolated gate transistors includes n-channel transistors.

10. A memory device having been programmed by subjecting isolated gate transistors to conditions that cause an impact ionization current.

11. The memory device of claim 10 wherein the memory device comprises:
a plurality of isolated gate transistors; and
sensing circuitry to sense whether any of the plurality of isolated gate transistors have been subjected to conditions that cause an impact ionization current.

12. The memory device of claim 10 wherein the memory device comprises an array of memory cells.

13. The memory device of claim 12 wherein each cell in the array of memory cells comprises an isolated gate transistor.

14. The memory device of claim 13 wherein the isolated gate transistor comprises an n-channel device having a drain coupled to a bit line, a gate coupled to a word line, and a source coupled to a reference potential node.

15. The memory device of claim 13 wherein the isolated gate transistor comprises a MOSFET device.

16. A method comprising programming a memory device by causing gate insulator degradation to at least one isolated gate transistor.

17. The method of claim 16 wherein causing gate insulator degradation comprises driving voltages on a gate node and a drain node of the at least one isolated gate transistor to cause an impact ionization current.

18. The method of claim 16 further comprising sensing whether the at least one isolated gate transistor has been subjected to gate insulator degradation.

19. The method of claim 18 wherein sensing comprises sensing a threshold voltage of the at least one isolated gate transistor.

20. An electronic system comprising:
a processing device;
a static random access memory coupled to the processing device; and
a one time programmable (OTP) memory coupled to the processing device, wherein the OTP memory includes an array of isolated gate transistors programmed by gate insulator degradation.

21. The electronic system of claim 20 wherein the processing device and the OTP memory are packaged together.

22. The electronic system of claim 21 wherein the processing device and the OTP memory are included on a common integrated circuit die.

23. The electronic system of claim 20 wherein the OTP memory further includes a sensing mechanism coupled to sense threshold voltage changes caused by the gate insulator degradation.
